(19) United States
(12) Patent Application Publication
(10) Pub. No.: US 2016/0353212 A1
(43) Pub. Date: Dec. 1, 2016

(54) RAISED SHOULDER MICRO ELECTRO MECHANICAL SYSTEM (MEMS) MICROPHONE

(71) Applicant: Knowles Electronics, LLC, Itasca, IL (US)

(72) Inventors: Eric J. Lautenschlager, Geneva, IL (US); Sandra F. Vos, East Dundee, IL (US)

(73) Assignee: Knowles Electronics, LLC, Itasca, IL (US)

(21) Appl. No.: 15/163,586

(22) Filed: May 24, 2016

Related U.S. Application Data
(60) Provisional application No. 62/166,334, filed on May 26, 2015.

(51) Int. Cl. H04R 19/04; H03H 11/04; H04R 19/00

(52) U.S. Cl. CPC H04R 19/04; H04R 19/005; H03H 11/04; H04R 2499/11; H04R 2201/003

(57) ABSTRACT

Microphone devices are disclosed. The microphone device includes a base, a lid, a side wall between the base and the lid, and a MEMS die. The side wall includes a first portion with a first width and a second portion with a second width disposed under the first portion. The first width is less than the second width such that a shoulder is formed on the second portion. The MEMS die is supported on the shoulder. The MEMS die includes a diaphragm and a back plate.

### CROSS REFERENCE TO RELATED APPLICATION

The present application claims the benefit of U.S. Provisional Patent Application No. 62/166,334, entitled “Raised Shoulder Micro Electro Mechanical System (MEMS) Microphone,” filed on May 26, 2015, the entirety of which is incorporated herein by reference.

### TECHNICAL FIELD

This application relates to construction of micro electro mechanical system (MEMS) microphones and, more specifically, to the configuration and arrangement of these devices.

### BACKGROUND

A microphone in general receives sound energy and converts the sound energy into an electrical signal. Various types of microphones have been in use over the years. One such type is a micro electro mechanical system (MEMS) microphone. MEMS microphones typically include a diaphragm and a back plate. Sound energy moves the diaphragm and this creates a changing electrical potential with the back plate thereby creating an electrical signal representative of the sound energy.

MEMS microphones have been installed in various devices. For example, MEMS microphones have been installed in devices such as cellular phones, tablets, and personal computers. In many of these devices, it is desirable to make the device as small as possible to satisfy the desire of consumers for smaller devices. Unfortunately, previous MEMS microphones were somewhat limited in the amount their size could be reduced. This, in turn, limited the amount of size reduction that was possible in the consumer device.

All of the problems listed above have resulted in some user dissatisfaction with previous approaches.

### SUMMARY

One embodiment of the disclosure relates to a microphone device comprising a base, a lid, and a side wall between the base and the lid. The side wall comprises a first portion with a first width, and a second portion with a second width disposed under the first portion. The first width is less than the second width such that a shoulder is formed on the second portion. A MEMS die is supported on the shoulder, the MEMS die comprising a diaphragm and a back plate. In some embodiments, the MEMS die is attached to the shoulder by an adhesive. In some embodiments, the microphone device further comprises an integrated circuit supported on the base and the MEMS die is vertically over the integrated circuit.

These and other features, together with the organization and manner of operation thereof, will become apparent from the following detailed description when taken in conjunction with the accompanying drawings.

### BRIEF DESCRIPTION OF THE DRAWINGS

FIG. 1 comprises a perspective drawing of a microphone according to various embodiments of the present invention;

FIG. 2 comprises a side cut-away drawing along line A-A of FIG. 1 according to various embodiments of the present invention.

In the following detailed description, reference is made to the accompanying drawings, which form a part hereof. In the drawings, similar symbols typically identify similar components, unless context dictates otherwise.

### DETAILED DESCRIPTION

Approaches are provided to configure a MEMS microphone so as to conserve space. In some aspects, the MEMS microphone includes a base, and a side wall. The side wall is configured to have a raised shoulder portion. The raised shoulder portion supports a MEMS die (including a diaphragm and back plate). The MEMS die is disposed vertically over an integrated circuit (e.g., an application specific integrated circuit (ASIC)) but is not directly physically touching the integrated circuit (although the MEMS die and the ASIC are electrically coupled together by electrical conductors).

In other words, the MEMS die or device is placed on a shoulder of a microphone wall. This allows the microphone assembly to be shortened (in a horizontal direction) allowing the microphone to be placed in devices that can be made much smaller because of this positioning. Positioning of the MEMS die during the manufacturing process for the microphone is easy since the MEMS die can be easily placed on the shoulder through the top of the microphone. A smaller footprint for the MEMS die is also achieved thereby decreasing the size of the device in which the MEMS microphone is deployed.

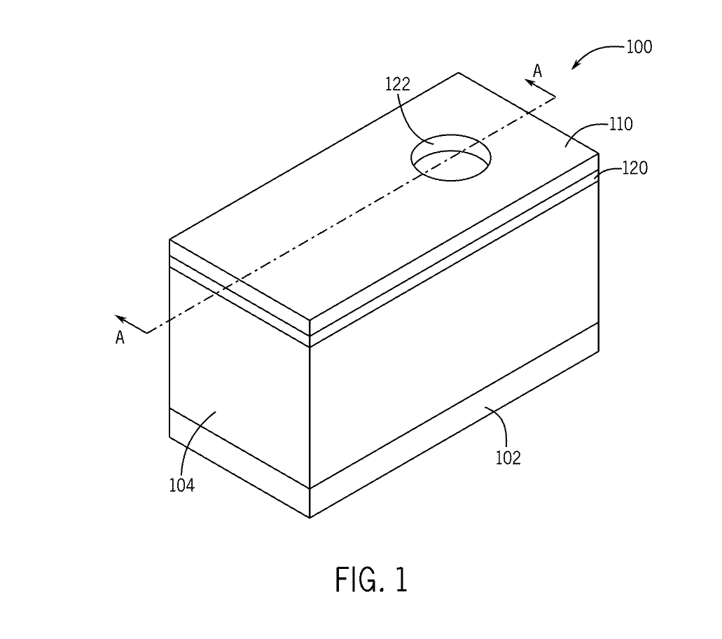

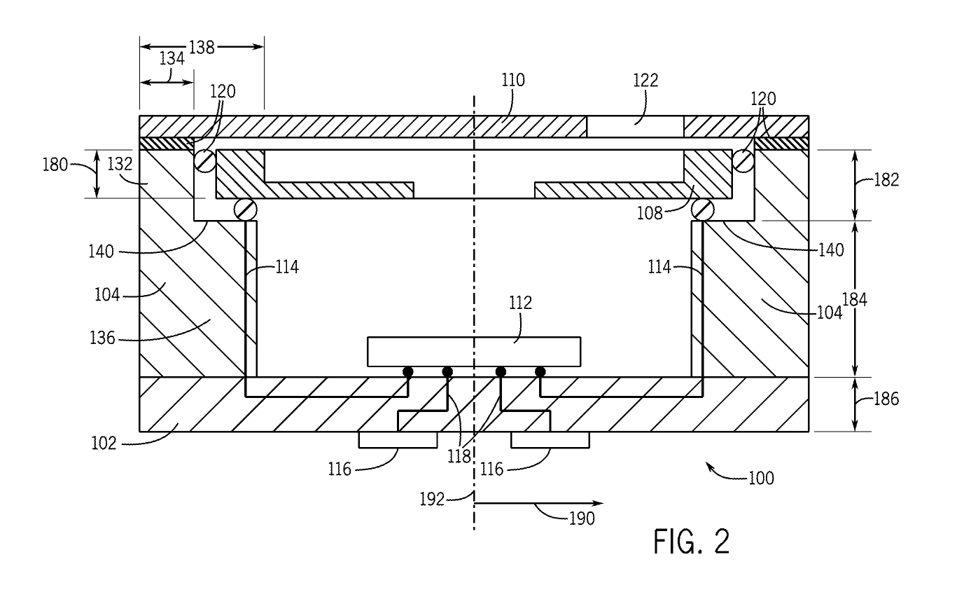

Referring now to FIG. 1 and FIG. 2, one example of a microphone assembly 100 includes a base 102, walls 104, a micro electro mechanical system (MEMS) device or die 108, and a lid 110. An integrated circuit (e.g., an application specific integrated circuit) 112 couples to the base 102.

The base 102 may be a printed circuit board (PCB) including multiple layers of material, or it may be made of ceramic materials or glass. The MEMS die or device 108 may include a diaphragm and a back plate. Sound energy moves the diaphragm and this creates a changing electrical potential with the back plate thereby creating an electrical signal representative of the sound energy. This electrical signal may be sent to the integrated circuit 112 for further processing.

The walls 104 include a first portion 132 with a first width or thickness 134. The walls also include a second portion 136 with a second width or thickness 138. The first width 134 is less than the second width 138. These may be separate pieces or one piece. This configuration produces an inside cross-section of the walls that is stepped in shape and that includes a stepped surface or shoulder 140. The MEMS device 108 is disposed on the stepped surface 140. The MEMS die 108 may be attached to the shoulder by any appropriate approach such as by glue, solder, or some other adhesive.

The integrated circuit 112 may perform various functions (e.g., noise removal) and may be connected to the base 102 via a flip chip connection. That is, the integrated circuit 112 may not be connected to the base 102 via wire bonds, but may be reversed and connected to the base 102 by solder bumps. In other examples, the integrated circuit 112 may not be flip chipped, but is connected to the base 102 by wires and a regular wire bond approach. More than one ASIC may be used ton increase functionality of the part, including but not limited to other sensors or signal processing.

The integrated circuit 112 is connected to the MEMS die 108 through electrical conductors 114. The electrical conductors 114 may be any combination of wires, vias (plated or filled), electrical traces, or combinations of these or other elements. The integrated circuit 112 is connected to the pads 116 via electrical conductors 118.

Seals 120 seal the lid 110 and the walls 104, and the MEMS die 108 and walls 104. These seals could be different materials or the same (conductive/non-conductive) and completed in either one or two manufacturing steps. A port 122 allows sound energy to enter the MEMS device 108 for a top port device. Conversely, a port can also be positioned in the base, 102, for a bottom port configuration.

It will be appreciate that the components and walls 104 described herein can have various dimensions. For example, a third distance 180 (of the MEMS device 108) may be approximately 200-250 micro meters, or higher or lower. A fourth distance 182 (from the top of MEMS cavity to the stepped surface 140) may be approximately 200-250 micro meters, or higher or lower. A fifth distance 184 (from the stepped surface 140 to the base 102) may be approximately 150-300 micro meters, or higher or lower. A sixth distance 186 (of the base 102) may be less than approximately 100 micro meters, or higher or lower. It will be appreciated that these distances are examples only and that other examples of other distances or dimensions are possible.

In one example of the operation of the system of FIG. 1 and FIG. 2, sound energy enters the apparatus 100 via port 122. The sound energy impacts the MEMS die or device 108, which includes a diaphragm and a back plate. Sound energy moves the diaphragm and this creates a changing electrical potential with the back plate thereby creating an electrical signal representative of the sound energy. This electrical signal is sent to the integrated circuit 112 for further processing via electrical conductors 114.

The integrated circuit 112 performs the further processing on the electrical signal (e.g., noise removal to mention one example). The processed signal is sent to the pads 116 via the electrical conductors 118. The pads 116 may couple to other electrical or electronic circuits within another consumer electronic device (e.g., a tablet, a cellular phone, or a personal computer to mention a few examples).

The raised shoulder portion (the stepped surface 140) supports the MEMS die 108. It will be appreciated that the MEMS die 108 is disposed or stacked vertically over the integrated circuit 112 but is not directly physically (or mechanically) touching the integrated circuit 112 (although the MEMS die 108 and the integrated circuit 112 are electrically coupled together by electrical conductors 114).

In other words, the MEMS die 108 is placed or disposed on a shoulder 140 of a microphone wall vertically over the integrated circuit 112 along the vertical axis 192. This allows the microphone assembly 100 to be shortened (in a horizontal direction or axis indicted by the label 190) allowing the microphone assembly 100 to be placed in devices that can be made much smaller because of this positioning. Positioning of the MEMS die 108 is also an easy process since the MEMS die can be easily placed on the shoulder 140 through the top of the microphone assembly 100. A smaller footprint for the MEMS die 108 is also achieved thereby decreasing the size of the device in which the MEMS microphone is deployed.

The herein described subject matter sometimes illustrates different components contained within, or connected with, different other components. It is to be understood that such depicted architectures are merely exemplary, and that in fact many other architectures can be implemented which achieve the same functionality.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

1. A microphone device comprising:
a base;
a lid;
a side wall between the base and the lid, the side wall comprising:
a first portion with a first width; and
a second portion with a second width disposed under the first portion, wherein the first width is less than the second width such that a shoulder is formed on the second portion; and
a MEMS die supported on the shoulder, the MEMS die comprising a diaphragm and a back plate.

2. The microphone device of claim 1, wherein a port is formed on the base that allows sound energy to reach the MEMS die.

3. The microphone device of claim 1, wherein a port is formed on the lid that allows sound energy to reach the MEMS die.

4. The microphone device of claim 1, wherein the base is a printed circuit board including multiple layers.

5. The microphone device of claim 1, wherein the first portion and the second portion are separate pieces.

6. The microphone device of claim 1, wherein the first portion and the second portion are one piece.

7. The microphone device of claim 1, wherein the MEMS die is attached to the shoulder by an adhesive.

8. The microphone device of claim 1, further comprising seals that seal the lid to the side wall.

9. The microphone device of claim 1, further comprising an integrated circuit supported on the base, wherein the MEMS die is vertically over the integrated circuit.

10. The microphone device of claim 9, wherein the MEMS die does not physically touch the integrated circuit.

11. The microphone device of claim 9, wherein the integrated circuit is an application specific integrated circuit (ASIC).

12. The microphone device of claim 9, wherein the integrated circuit is configured to process an electrical signal produced by the MEMS die.

13. The microphone device of claim 12, wherein the integrated circuit is configured to remove noises from the electrical signal.

14. The microphone device of claim 9, wherein the integrated circuit is electrically connected to the base by solder bumps via a flip chip connection.

15. The microphone device of claim 9, wherein the integrated circuit is electrically connected to the base via wire bonds.

16. The microphone device of claim 9, wherein the base comprises pads electrically connected to the integrated circuit, wherein the pads are coupled to electrical circuits within a consumer electronic device.

17. The microphone device of claim 16, wherein the consumer electronic device is one of a tablet, a cellular phone, or a personal computer.

18. The microphone device of claim 9, wherein the integrated circuit is electrically connected to the MEMS die through at least one of wires, conductive vias, and electrical traces.

19. The microphone device of claim 9, wherein the base comprises pads connected to the integrated circuit.

20. The microphone device of claim 1, wherein the MEMS die is placed on the shoulder through a top of the microphone device.
